(19) United States
(12) Patent Application Publication
(10) Pub. No.: US 2025/0199042 A1
(43) Pub. Date: Jun. 19, 2025

(54) SEMICONDUCTOR CHIP

(71) Applicant: SONY SEMICONDUCTOR SOLUTIONS CORPORATION, Kanagawa (JP)

(72) Inventor: Yuta TOEDA, Kanagawa (JP)

(73) Assignee: SONY SEMICONDUCTOR SOLUTIONS CORPORATION, Kanagawa (JP)

(21) Appl. No.: 18/846,363

(22) PCT Filed: Mar. 25, 2022
(86) PCT No.: PCT/JP2022/014355

§ 371 Date: Sep. 12, 2024

(51) Int. Cl. G01R 27/32; H01P 5/18

(52) U.S. Cl. CPC G01R 27/32; H01P 5/184

(57) ABSTRACT

The present disclosure relates to a semiconductor chip that makes it possible to provide a directional coupler whose frequency band is a wide band and that has a small area. The semiconductor chip includes a directional coupler that uses a resistance bridge circuit that includes first to third resistance circuit elements and a measurement target circuit. The technology of the present disclosure is applicable to, for example, a vector network analyzer.

### TECHNICAL FIELD

The present disclosure relates to a semiconductor chip and, more particularly, relates to a semiconductor chip whose frequency band is a wide band and that includes a directional coupler of a small area.

### BACKGROUND ART

A vector network analyzer includes a signal source and three receivers of an R channel, an A channel, and a B channel, and, in addition, a directional coupler that separates an incident wave and a reflected wave. Examples of the directional coupler are known as a directional coupler that includes a transmission line formed on a substrate and a directional coupler that uses a waveguide (see, for example, PTL 1).

### CITATION LIST

### Patent Literature

PTL 1: JP 05-264835A

### SUMMARY

### Technical Problem

To achieve lower cost of a vector network analyzer, a directional coupler whose frequency band is a wide band and that has a small area is demanded.

With the foregoing in view, it is an object of the present disclosure to make it possible to provide a directional coupler whose frequency band is a wide band and that has a small area.

### Solution to Problem

A semiconductor chip according to a first aspect of the present disclosure includes a directional coupler that uses a resistance bridge circuit that includes first to third resistance circuit elements and a measurement target circuit.

According to the first aspect of the present disclosure, the directional coupler that uses the resistance bridge circuit that includes the first to third resistance circuit elements and the measurement target circuit is provided to a semiconductor chip.

The semiconductor chip may be an independent device or may be a module incorporated in another device.

### BRIEF DESCRIPTION OF DRAWINGS

FIG. 1 is a block diagram illustrating a configuration example of a first embodiment of a vector network analyzer according to the present technique.

FIG. 2 is a view for describing an S parameter measured by the vector network analyzer.

FIG. 3 is a view for describing the S parameter measured by the vector network analyzer.

FIG. 4 is a view illustrating a specific circuit configuration of a directional coupler in FIG. 1.

FIG. 5 is a block diagram illustrating a configuration example of a second embodiment of the vector network analyzer according to the present disclosure.

FIG. 6 is a view illustrating a specific circuit configuration of a directional coupler in FIG. 5.

FIG. 7 is a view illustrating a first modified example of the directional coupler according to the first embodiment.

FIG. 8 is a view illustrating a second modified example of the directional coupler according to the first embodiment.

### DESCRIPTION OF EMBODIMENTS

Modes for embodying the technique of the present disclosure (hereinafter referred to as embodiments) will be described below with reference to the accompanying drawings. In the present specification and the drawings, components having substantially the same functional configuration will be denoted by the same reference numerals, and thus repeated descriptions thereof will be omitted. The description will be made in the following order.
1. Configuration Example of First Embodiment of VNA
2. Description of Measurement Parameter of VNA
3. Specific Circuit Configuration Example of Directional Coupler
4. Configuration Example of Second Embodiment of VNA
5. Specific Circuit Configuration Example of Directional Coupler
6. Other Circuit Configuration Example of Directional Coupler

### <1. Configuration Example of First Embodiment of VNA>

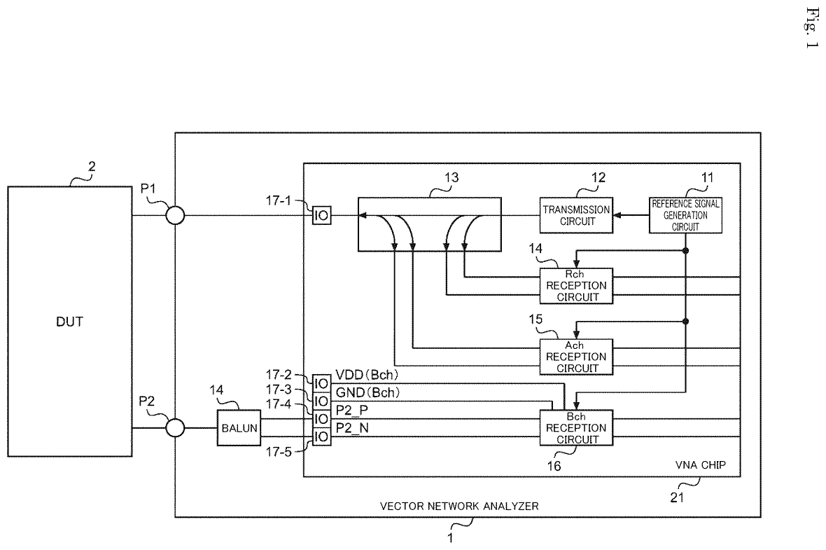

FIG. 1 is a block diagram illustrating a configuration example of the first embodiment of a Vector Network Analyzer (hereinafter, referred to as a VNA) according to the present technique.

A VNA 1 is a measurement device that connects a measurement target circuit 2 (hereinafter, referred to as the DUT 2) between two ports P1 and P2, and measures an S parameter (reflection characteristics and transmission characteristics) of the DUT 2.

The VNA 1 includes a VNA chip 21 formed by integrating circuits such as a reference signal generation circuit 11, a transmission circuit 12, a directional coupler 13, an Rch (R channel) reception circuit 14, an Ach (A channel) reception circuit 15, a Bch (B channel) reception circuit 16, and a plurality of input/output terminals 17 on one chip.

An input/output terminal 17-1 of the plurality of input/output terminals 17 of the VNA chip 21 is a terminal that outputs a test signal, and is connected with the port P1. An input/output terminal 17-2 is a terminal that receives an input of a power supply voltage VDD, an input/output terminal 17-3 is a terminal that is connected with a grand (GND), and input/output terminals 17-4 and 17-5 are terminals that are connected with the port P2 via a balun 22 and receive an input of a signal (transmitted signal) having transmitted through the DUT 2.

The reference signal generation circuit 11 is configured as a PLL circuit or the like, generates a reference signal that serves as a reference in the circuit in the chip, and supplies the reference signal to each of the transmission circuit 12, the directional coupler 13, the Rch reception circuit 14, the Ach reception circuit 15, and the Bch reception circuit 16.

The transmission circuit 12 generates a test signal of a predetermined frequency fb based on the reference signal from the reference signal generation circuit 11, and supplies the test signal to the directional coupler 13. For example, the transmission circuit 12 can generate and output as a test signal a sine wave of the arbitrary frequency fb within a range of 1 GHz to 9 GHz.

The directional coupler 13 distributes an input signal that is the test signal from the transmission circuit 12 and is input to the DUT 2, and separates a reflection signal that is the test signal reflected by the DUT 2. More specifically, the directional coupler 13 outputs part of the test signals from the transmission circuit 12 to the input/output terminal 17-1, and outputs the rest of the distributed test signal to the Rch reception circuit 14. Furthermore, the directional coupler 13 extracts the reflection signal reflected and input by the DUT 2, and outputs the reflection signal to the Ach reception circuit 15.

The Rch reception circuit 14 receives the input signal supplied from the directional coupler 13.

The Ach reception circuit 15 receives the reflection signal supplied from the directional coupler 13.

The Bch reception circuit 16 receives the transmitted signal input via the port P2 and having transmitted through the DUT 2.

### <2. Description of Measurement Parameter of VNA>

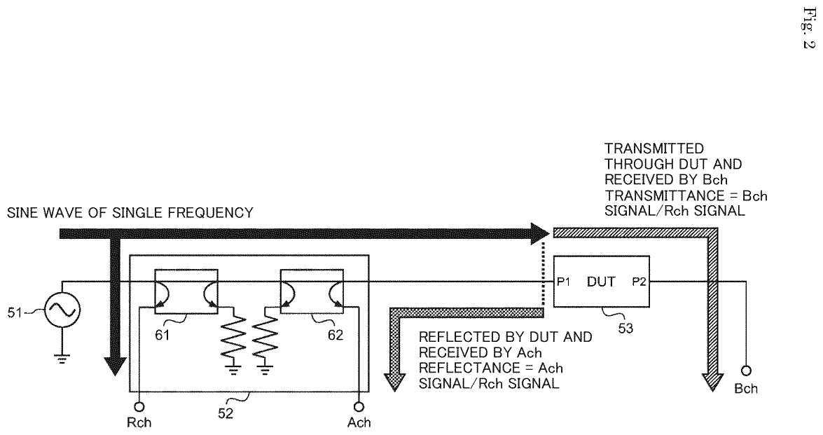

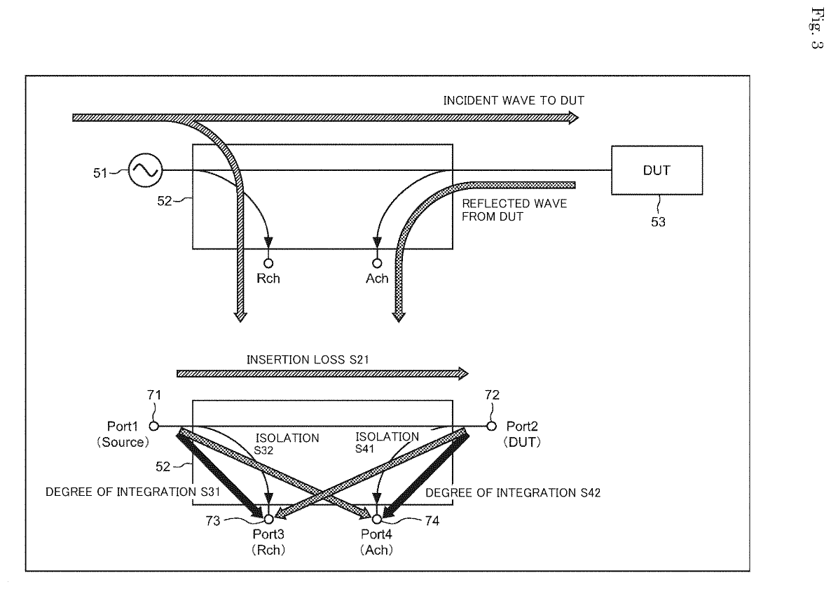

The S parameter measured by the VNA 1 will be described with reference to FIGS. 2 and 3.

A signal source 51 outputs the sine wave of the single frequency fb as the test signal. The output test signal is input to a measurement target circuit 53 through a directional coupler 52.

The directional coupler 52 includes an R channel side directional coupler 61 (hereinafter, referred to as the Rch directional coupler 61) and an A channel side directional coupler 62 (hereinafter, referred to as the Ach directional coupler 62). Part of the test signals that is an incident wave is separated by the Rch directional coupler 61 and is input to an Rch reception circuit. A reflection signal reflected by the measurement target circuit 53 is separated by the Ach directional coupler 62, and is input to an Ach reception circuit. On the other hand, the test signal having transmitted through the measurement target circuit (DUT) 53 is input to a Bch reception circuit.

The VNA 1 can measure reflectance that is transmission characteristics from the port P1 to the port P1 of the measurement target circuit 53 when the reflection signal received by the Ach reception circuit is seen based on the test signal received by the Rch reception circuit as the reference. That is, the VNA1 can measure reflectance=Ach signal/Rch signal.

Furthermore, the VNA 1 can measure transmittance that is transmission characteristics from the port P1 to the port P2 of the measurement target circuit 53 when the transmitted signal received by the Bch reception circuit is seen based on the test signal received by the Rch reception circuit as the reference. That is, the VNA1 can measure transmittance=Bch signal/Rch signal.

Hence, although, ideally, the test signal from the signal source 51 is distributed only to the Rch reception circuit and the reflection signal from the measurement target circuit 53 is distributed only to the Ach reception circuit as illustrated in the upper part in FIG. 3, there is actually leak (isolation). A larger ratio of a signal that needs to be acquired, and the leak indicates higher directionality, and is desirable.

As illustrated in the lower part in FIG. 3, in a case where a port connected with the signal source 51 is a first port 71, a port connected with the measurement target circuit 53 is a second port 72, a port connected with the Rch reception circuit is a third port 73, and a port connected with the Ach reception circuit is a fourth port 74, and insertion loss of the directional coupler 52 is S21, the degree of coupling of the test signal is S31, isolation is S32, the degree of coupling of the reflection signal is S42, and isolation is S41, directionality D_{Rch} on the Rch side can be expressed by D_{Rch}=S31−S21−S32, and directionality D_{Ach} on the Ach side can be expressed by D_{Ach}=S21+S42−S41. Although, as for the directionality D_{Rch} on the Rch side, the insertion loss S21 contributes to improvement of the directionality D_{Rch}, as for the directionality D_{Ach} on the Ach side, only the insertion loss S21 deteriorates the directionality D_{Ach} and therefore it is more difficult to improve the directionality D_{Ach} on the Ach side.

### <3. Specific Circuit Configuration Example of Directional Coupler>

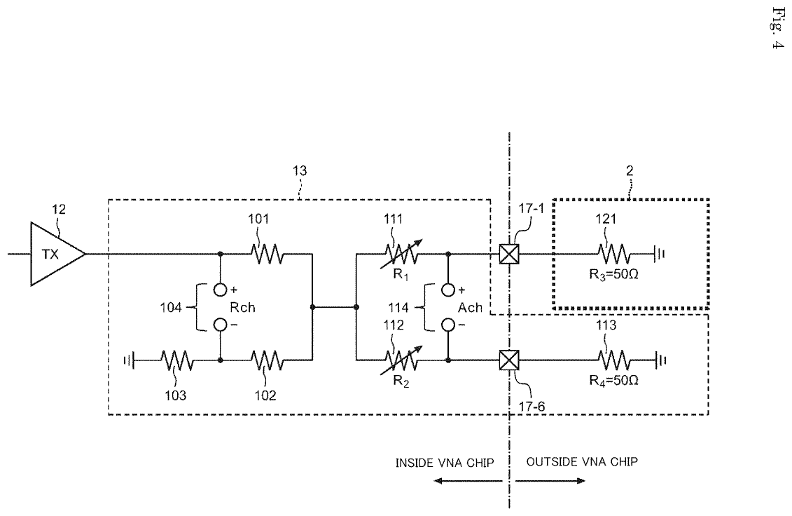

FIG. 4 illustrates a specific circuit configuration of the directional coupler 13 in FIG. 1.

The directional coupler 13 includes resistance elements 101 to 103 and an R channel output terminal 104, and resistance elements 111 to 113 and an A channel output terminal 114. Here, although the resistance elements 101 to 103 and the R channel output terminal 104, and the resistance elements 111 and 112 and the A channel output terminal 114 are formed inside the VNA chip 21, the resistance element 113 is formed outside the VNA chip 21. The input/output terminal 17-1 is a terminal that outputs the test signal, and an input/output terminal 17-6 is a terminal for connecting the resistance element 112 formed inside the chip and the resistance element 113 formed outside the chip.

The resistance elements 101 to 103 constitute an Rch directional coupler, extracts part of the test signals input from the transmission circuit 12, and outputs the part of the test signals to the Rch reception circuit 14 via the R channel output terminal 104. That is, the test signal input from the transmission circuit 12 is distributed to the resistance elements 111 and 112 and the resistance element 102, and the test signal having flown to the resistance element 102 is output to the Rch reception circuit 14 via the R channel output terminal 104. The resistance element 103 is a terminating resistance inside the Rch directional coupler.

The resistance elements 111 to 113 constitute an Ach directional coupler, and output the test signal input from the transmission circuit 12 to the DUT 2 via the input/output terminal 17-1, extract the reflection signal reflected by the DUT 2, and output the reflection signal to the A channel reception circuit 114. The reflection signal output to the A channel output terminal 114 is supplied to the Ach reception circuit 15. The resistance elements 111 and 112 of the Ach directional coupler are configured as variable resistance elements whose resistance values are changeable. The resistance value of the resistance element 111 is R₁, and the resistance value of the resistance element 112 is R₂. The resistance element 113 is a terminating resistance inside the Ach directional coupler.

The input/output terminal 17-1 is connected with the DUT 2 at a time of measurement of the S parameter, and is connected with a reference resistance element 121 that has a reference resistance value as illustrated in FIG. 4 at a time of adjustment of the VNA chip 21 such as a time of adjustment before shipping of the VNA chip 21. The reference resistance value is generally 50Ω. The resistance value of the resistance element 113 is adjusted to the resistance value of the reference resistance element 121 that has the reference resistance value. In the present embodiment, the reference resistance value is 50Ω, and a resistance value R₃ and a resistance value R₄ are also 50Ω in total.

The resistance elements 111 to 113 that constitute the Ach directional coupler constitute a resistance bridge circuit together with the reference resistance element 121, and the resistance values of the resistance elements 111 and 112 that are the variable resistance elements are adjusted such that a balance condition of the bridge circuit holds at the time of adjustment of the VNA chip 21. That is, the resistance values R₁ and R₂ of the resistance elements 111 and 112 are adjusted such that R₁/R₂=R₃/R₄ holds in the resistance bridge circuit in which the resistance element 111 (first resistance element) and the reference resistance element 121 connected in series, and the resistance element 112 (second resistance element) and the resistance element 113 (third resistance element) connected in series are connected in parallel. In other words, in a case where the balance condition of the bridge circuit holds, since currents flowing on an upper side and a lower side of the bridge circuit become equal, and the current flowing to the A channel output terminal 114 becomes zero, the resistance values R₁ and R₂ of the resistance elements 111 and 112 are adjusted such that the current flowing to the A channel output terminal 114 becomes zero.

When the DUT 2 is connected to the input/output terminal 17-1 at the time of measurement of the S parameter after adjustment of the resistance values of the resistance elements 111 and 112, the current corresponding to an impedance of the DUT 2 flows on the upper side of the bridge circuit, and the current corresponding to the resistance value R₄ of the resistance element 113=50Ω flows on the lower side of the bridge circuit. In other words, a signal corresponding to the impedance of the DUT 2 based on the resistance value R₄ of the resistance element 113=50Ω as the reference is output to the A channel output terminal 114, so that it is possible to detect the reflection signal.

As described above, by using the resistance bridge circuit for the directional coupler 13, it is possible to miniaturize the directional coupler 13 while making it possible to support a wide band, and incorporate the directional coupler 13 in the semiconductor chip. The directional coupler 13 is implemented using the semiconductor chip as the VNA chip 21, so that it is possible to provide a VNA of a small area whose frequency band is a wide band at low cost.

The resistance elements 111 and 112 that constitute part of the resistance bridge circuit are the variable resistance elements whose resistance values are changeable, so that it is possible to adjust the resistance values R₁ and R₂ such that the balance condition of the bridge circuit holds. Consequently, it is possible to improve the directionality of the directional coupler 13, and improve the performance of the directional coupler 13.

Furthermore, the DUT 2 is arranged outside the VNA chip 21, and is connected with the directional coupler 13 via the input/output terminal 17-1, and is configured such that the resistance element 113 associated with the DUT 2 among the resistance elements 112 and 113 of the directional coupler 13 connected in parallel to the resistance element 111 and the DUT 2 is also arranged outside the VNA chip 21, and is connected via the input/output terminal 17-6. Arrangement conditions on the upper side and the lower side of the bridge circuit are matched and directionality is provided to prevent deterioration of the directionality and improve the performance of the directional coupler 13.

### <4. Configuration Example of Second Embodiment of VNA>

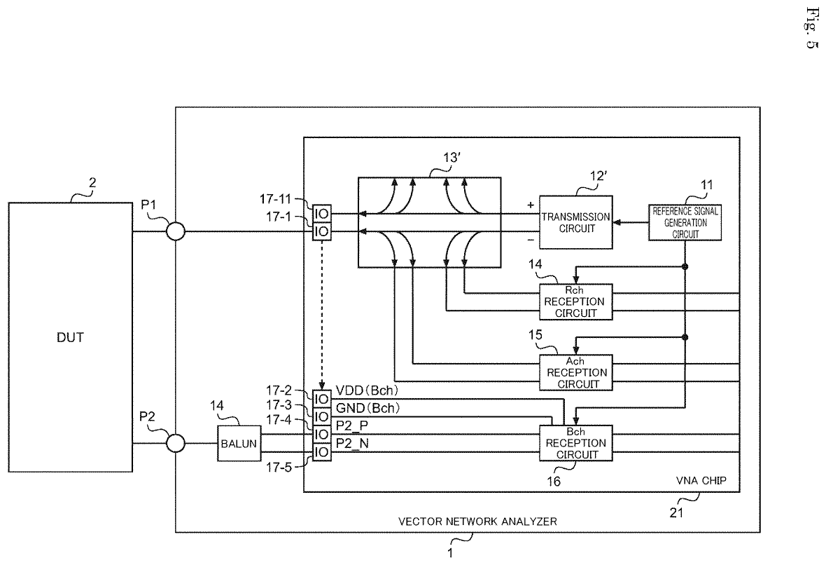

FIG. 5 is a block diagram illustrating a configuration example of the second embodiment of the Vector Network Analyzer (VNA) according to the present disclosure.

In the second embodiment in FIG. 5, portions corresponding to those in the first embodiment illustrated in FIG. 1 are denoted by the same reference signs, description of the portions will be appropriately omitted, and description will be focused on different portions from those in the first embodiment.

A difference is that, while the VNA 1 uses a single-ended signal as a test signal in the above-described first embodiment, test signals of differential signals are used in the second embodiment.

In the VNA 1 according to the second embodiment, the transmission circuit 12 and the directional coupler 13 in the first embodiment illustrated in FIG. 1 are replaced with a transmission circuit 12′ and a directional coupler 13′. Furthermore, an input/output terminal 17-11 is added as one of the plurality of input/output terminals 17. Other components of the VNA 1 are similar to those of the VNA 1 in FIG. 1.

The transmission circuit 12′ generates test signals of the predetermined frequency fb as differential signals, and supplies the differential signals to the directional coupler 13′. More specifically, a first test signal and a second test signal having the identical frequency fb and a relationship of opposite phases are generated by the transmission circuit 12′, and input to the directional coupler 13′.

The directional coupler 13′ performs the same operation as that of the directional coupler 13 according to the above-described first embodiment on the first test signal among the first test signal and the second test signal from the transmission circuit 12′. That is, the directional coupler 13′ outputs part of the first test signal from the transmission circuit 12′ to the input/output terminal 17-1, and outputs the rest of the distributed first test signal to the Rch reception circuit 14. Furthermore, the directional coupler 13′ outputs the reflection signal reflected and input by the DUT 2 to the Ach reception circuit 15.

On the other hand, the directional coupler 13′ distributes the second test signal similarly to the first test signal, and outputs the second test signal to the input/output terminal 17-11.

Isolation characteristics between the ports P1 and P2 connected to the DUT 2 are important for the performance of the VNA 1. In a case where leak between the ports P1 and P2 is great, it is not possible to accurately measure the transmittance. Factors of the leak between the ports P1 and P2 include leak via an IO ring (not illustrated in FIG. 5) formed at a position at which the plurality of input/output terminals 17 of the VNA chip 21 overlap as indicated by a broken line arrow in FIG. 5. That is, part of the test signals to be output to the port P1 reach the input/output terminals 17-4 and 17-5 associated with the port P2 via the IO ring inside the chip that is a path other than a path between the ports P1 and P2.

Hence, the VNA 1 according to the second embodiment differentiates the test signals, outputs the first test signal to the input/output terminal 17-1, and outputs the second test signal to the input/output terminal 17-11. Consequently, even when leak occurs between the ports P1 and P2, a leak signal passing via the IO ring also becomes a differential signal, so it is possible to substantially cancel the leak signal and reduce the signal that reaches the input/output terminals 17-4 and 17-5 via the IO ring. Consequently, it is possible to improve the isolation characteristics between the ports P1 and P2, and further improve the performance of the VNA 1.

### <5. Specific Circuit Configuration Example of Directional Coupler>

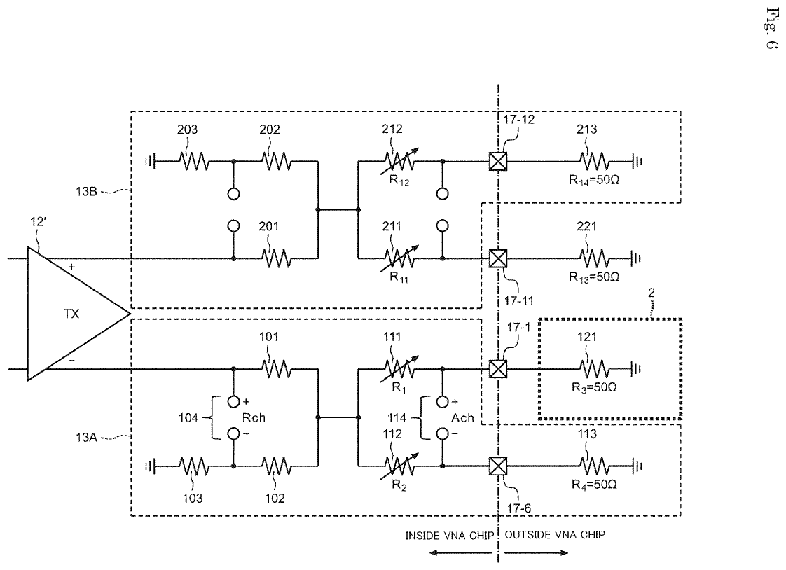

FIG. 6 illustrates a specific circuit configuration of the directional coupler 13′ in FIG. 5.

The directional coupler 13′ includes a directional coupler 13A that processes the first test signal that is the differential signal output from the transmission circuit 12′, and a directional coupler 13B that processes the second test signal. Each configuration of the directional coupler 13A for the first test signal and the directional coupler 13B for the second test signal are similar to that of the directional coupler 13 according to the first embodiment.

Each resistance element that constitutes the directional coupler 13A for the first test signal is denoted by the same reference numeral as that of the directional coupler 13 according to the first embodiment, and employs an identical configuration to that of the directional coupler 13 according to the first embodiment.

The directional coupler 13B for the second test signal includes resistance elements 201 to 203 and resistance elements 211 to 213. The resistance elements 201 to 203 correspond to the resistance elements 101 to 103 of the directional coupler 13A for the first test signal, and the resistance elements 211 to 213 correspond to the resistance elements 111 to 113 of the directional coupler 13A for the first test signal. The resistance elements 211 and 212 are configured as variable resistance elements, a resistance value of the resistance element 211 is R₁₁, a resistance value of the resistance element 212 is R₁₂, a resistance value of a resistance element 221 is R₁₃, and a resistance value of the resistance element 213 is R₁₄.

Here, that the resistance elements 201 to 203 and the resistance element 211 and 212 are formed inside the VNA chip 21, and the resistance elements 213 and 221 are formed outside the VNA chip 21 is also identical to that of the directional coupler 13A for the first test signal, in other words, the directional coupler 13 according to the first embodiment.

The input/output terminal 17-11 is a terminal that corresponds to the input/output terminal 17-1 for the first test signal, and outputs the second test signal. A resistance element 221 corresponding to the reference resistance element 121 for the first test signal is connected outside the VNA chip 21 of the input/output terminal 17-11. The resistance element 213 corresponding to the resistance element 113 for the first test signal is connected outside the VNA chip 21 of the input/output terminal 17-12. The resistance values of the resistance elements 221 and 213 are each same 50Ω as those of the reference resistance element 121 and the resistance element 113.

That directional coupler 13′ that uses the first test signal and the second test signal that are the differential signals can be configured as described above. The first test signal is output to the DUT 2 from the port P1 via the input/output terminal 17-1. The second test signal is output to the dummy resistance element 221 via the input/output terminal 17-11.

In the above-described second embodiment, too, by using the resistance bridge circuit for the directional coupler 13′, it is possible to miniaturize the directional coupler 13′ while making it possible to support a wide band, and incorporate the directional coupler 13′ in the semiconductor chip. The directional coupler 13′ is implemented using the semiconductor chip as the VNA chip 21, so that it is possible to provide a VNA of a small area whose frequency band is a wide band at low cost.

The directional coupler 13A for the first test signal and the directional coupler 13B for the second test signal employ the identical resistance bridge circuit configuration, so that it is possible to improve performance of the directional coupler 13′ similarly to the above-described first embodiment.

### <6. Other Circuit Configuration Example of Directional Coupler>

Although the directional coupler 13 (13′) includes only a plurality of resistance elements in the above-described first and second embodiments, circuit elements other than resistance elements such as circuits including capacitive elements, inductors, or semiconductor elements can constitute the directional coupler 13.

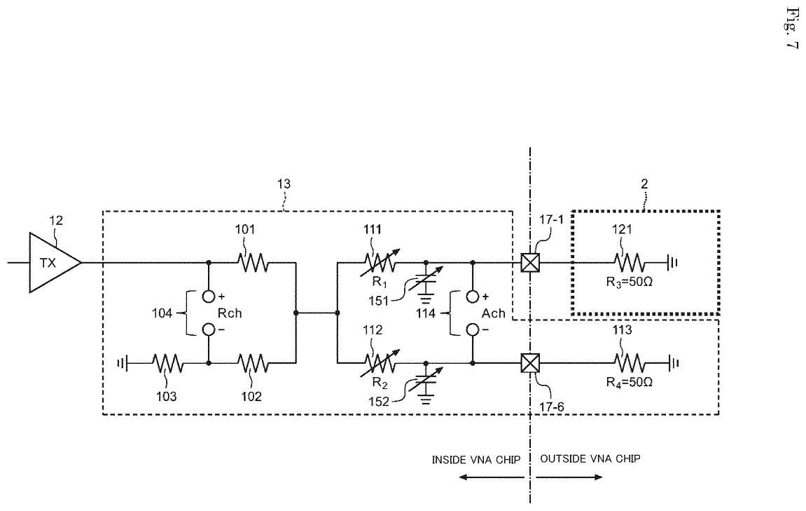

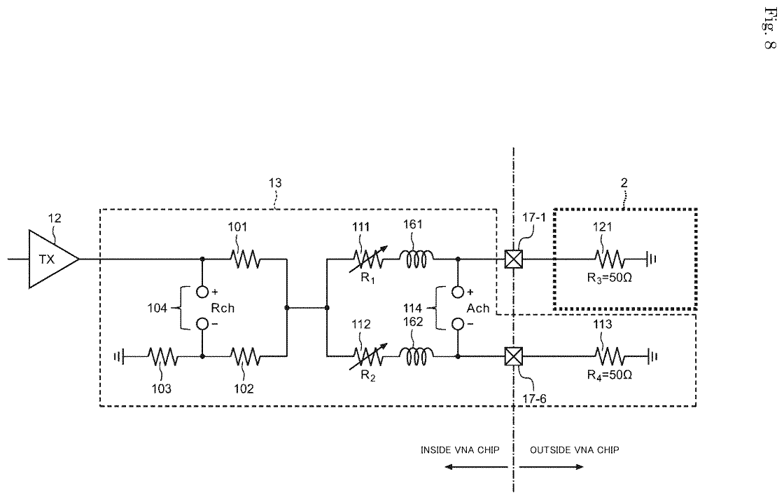

A configuration example of the directional coupler 13 including the circuit element other than the resistance element will be described with reference to FIGS. 7 and 8.

In FIGS. 7 and 8, portions common to those of the directional coupler 13 in the first embodiment illustrated in FIG. 4 are denoted by the same reference numerals, and descriptions of such portions will be omitted as appropriate.

FIG. 7 illustrates a first modified example of the directional coupler 13 illustrated in FIG. 4 and an example of the directional coupler 13 including a capacitive element as the circuit element other than the resistance element.

Compared to the directional coupler 13 according to the first embodiment, the directional coupler 13 in FIG. 7 includes a capacitive element 151 added between the resistance element 111 and the input/output terminal 17-1, and a capacitive element 152 added between the resistance element 112 and the input/output terminal 17-6. The capacitive elements 151 and 152 are each a capacitive element whose capacitance is variable, and provided to adjust the balance condition on the upper and lower sides of the bridge circuit.

FIG. 8 illustrates a second modified example of the directional coupler 13 illustrated in FIG. 4 and an example of the directional coupler 13 including an inductor as the circuit element other than the resistance element.

Compared to the directional coupler 13 according to the first embodiment, the directional coupler 13 in FIG. 8 includes an inductor 161 added between the resistance element 111 and the input/output terminal 17-1, and an inductor 162 added between the resistance element 112 and the input/output terminal 17-6. The inductors 161 and 162 are provided, so that it is possible to improve the frequency characteristics and achieve a wider band of the test signal

As described above, the directional coupler 13 can constitute the measurement target circuit and the resistance bridge circuit using at least one or more resistance circuit elements that are resistance elements, capacitive elements, inductors or semiconductor elements.

The embodiments of the present disclosure are not limited to the above-described embodiments, and various modifications can be made without departing from the essential spirit of the technology of the present disclosure.

For example, a combination of all or part of the above-described plurality of embodiments may be employed.

The advantageous effects described in the present specification are merely exemplary and are not limited, and other advantageous effects of the advantageous effects described in the present specification may be achieved.

The technique of the present disclosure can be configured as follows.

(1)

A semiconductor chip includes a directional coupler that uses a resistance bridge circuit that includes first to third resistance circuit elements and a measurement target circuit.

(2)

In the semiconductor chip described in above (1), the resistance bridge circuit employs a configuration where the first resistance circuit element and the measurement target circuit connected in series, and the second resistance circuit element and the third resistance circuit element connected in series are connected in parallel.

(3)

In the semiconductor chip described in above (2), the first and second resistance circuit elements are configured as variable resistance circuit elements whose resistance values are changeable, and, are configured such that, in a case where a reference resistance circuit element is connected to an input/output terminal that connects the measurement target circuit to the directional coupler, the resistance values of the first and second resistance circuit elements are adjusted such that a balance condition holds in the resistance bridge circuit.

(4)

In the semiconductor chip described in above (2) or (3), the third resistance circuit element is formed outside the semiconductor chip.

(5)

The semiconductor chip according to any one of above (1) to (4) further includes a transmission circuit that generates test signals of a predetermined frequency and supplies the test signals to the directional coupler.

(6)

In the semiconductor chip described in above (5), the transmission circuit generates the test signals of differential signals, and supplies the test signals to the directional coupler.

(7)

In the semiconductor chip described in above (6), the test signals of the differential signals are a first test signal and a second test signal, and the directional coupler includes a first directional coupler for the first test signal and a second directional coupler for the second test signal.

(8)

In the semiconductor chip described in above (7), each of the first and second directional couplers employs a configuration that uses the resistance bridge circuit.

(9)

In the semiconductor chip described in above (8), the resistance bridge circuit employs a configuration where the first resistance circuit element and the measurement target circuit connected in series, and the second resistance circuit element and the third resistance circuit element connected in series are connected in parallel, and the third resistance circuit element is formed outside the semiconductor chip.

### REFERENCE SIGNS LIST

1 Vector network analyzer (VNA)
2 Measurement target circuit
11 Reference signal generation circuit
12, 12′ Transmission circuit
13, 13′, 13A, 13B Directional coupler
14 Rch (R channel) reception circuit
15 Ach (A channel) reception circuit
16 Bch (B channel) reception circuit
17-1 to 17-6, 17-11, 17-12 Input/output terminal
21 VNA chip
22 Balun
101 to 103 Resistance element
104 R channel output terminal
111 to 113 Resistance element
114 A channel output terminal
121 Reference resistance element
201 to 203 Resistance element
211 to 213 Resistance element
221 Resistance element

What is claimed is:

1. A semiconductor chip, comprising:
a directional coupler that uses a resistance bridge circuit that includes first to third resistance circuit elements and a measurement target circuit.

2. The semiconductor chip according to claim 1, wherein the resistance bridge circuit employs a configuration where the first resistance circuit element and the measurement target circuit connected in series, and the second resistance circuit element and the third resistance circuit element connected in series are connected in parallel.

3. The semiconductor chip according to claim 2, wherein
the first and second resistance circuit elements are configured as variable resistance circuit elements whose resistance values are changeable, and,
are configured such that, in a case where a reference resistance circuit element is connected to an input/output terminal that connects the measurement target circuit to the directional coupler, the resistance values of the first and second resistance circuit elements are adjusted such that a balance condition holds in the resistance bridge circuit.

4. The semiconductor chip according to claim 2, wherein the third resistance circuit element is formed outside the semiconductor chip.

5. The semiconductor chip according to claim 1, further comprising a transmission circuit that generates test signals of a predetermined frequency and supplies the test signals to the directional coupler.

6. The semiconductor chip according to claim 5, wherein the transmission circuit generates the test signals of differential signals, and supplies the test signals to the directional coupler.

7. The semiconductor chip according to claim 6, wherein
the test signals of the differential signals are a first test signal and a second test signal, and
the directional coupler includes a first directional coupler for the first test signal and a second directional coupler for the second test signal.

8. The semiconductor chip according to claim 7, where each of the first and second directional couplers employs a configuration that uses the resistance bridge circuit.

9. The semiconductor chip according to claim 8, wherein
the resistance bridge circuit employs a configuration where the first resistance circuit element and the measurement target circuit connected in series, and the second resistance circuit element and the third resistance circuit element connected in series are connected in parallel, and
the third resistance circuit element is formed outside the semiconductor chip.
